(19) United States
(12) Patent Application Publication
(10) Pub. No.: US 2026/0047316 A1
(43) Pub. Date: Feb. 12, 2026

(54) DISPLAY DEVICE, VEHICLE INCLUDING THE SAME, ELECTRONIC DEVICE INCLUDING THE SAME, AND METHOD FOR FABRICATING DISPLAY DEVICE

(71) Applicant: Samsung Display Co., Ltd., Yongin-si (KR)

(72) Inventor: Chun Gi YOU, Yongin-si (KR)

(21) Appl. No.: 19/227,242

(22) Filed: Jun. 3, 2025

(30) Foreign Application Priority Data
Aug. 12, 2024 (KR) 10-2024-0107276

(51) Int. Cl. H10K 59/80; B60K 35/22; H10K 59/122; H10K 59/32

(52) U.S. Cl. CPC H10K 59/80517; B60K 35/22; H10K 59/122; H10K 59/32; H10K 59/80515

(57) ABSTRACT

A display device, a vehicle, and a method for fabricating the display device capable of preventing short circuit (or reducing a degree or occurrence of short circuit) between an anode electrode and a cathode electrode are disclosed. The display device may include: a substrate; an anode electrode on the substrate; a light emitting stack on the anode electrode; a pixel defining layer on the light emitting stack and having a trench; and a cathode electrode on the light emitting stack and the pixel defining layer. The anode electrode may include: a plurality of conductive (e.g., electrically conductive) layers; a protruding pattern that protrudes toward the light emitting stack from one selected from among the plurality of conductive (e.g., electrically conductive) layers; and an insulating (e.g., electrically insulating) layer around (e.g., surrounding) the protruding pattern and including silver and nitrogen.

### CROSS-REFERENCE TO RELATED APPLICATION

The present application claims priority to and the benefit of Korean Patent Application No. 10-2024-0107276, filed on Aug. 12, 2024, in the Korean Intellectual Property Office, the entire disclosure of which is incorporated herein by reference.

### BACKGROUND

### 1. Field

One or more embodiments of the present disclosure relate to display devices, and, for example, to display devices, vehicles including display devices, and methods for fabricating display devices capable of preventing short circuit (or reducing a degree or occurrence of short circuit) between an anode electrode and a cathode electrode.

### 2. Description of the Related Art

With the advancement of multimedia technology, the significance of display devices has increased. Consequently, one or more types of display devices, such as liquid crystal displays (LCDs) and/or organic light-emitting diode (OLED) displays, are being utilized.

Among the display devices, the organic light emitting diode (OLED) displays generate (e.g., display) images by using organic light-emitting elements that produce light through the recombination of electrons and holes. The organic light emitting diode displays offer fast response times, high luminance, wide viewing angles, and low power consumption.

### SUMMARY

One or more aspects of embodiments of the present disclosure are directed toward a display device, a vehicle, and a method for fabricating the display device capable of preventing short circuit (or reducing a degree or occurrence of short circuit) between an anode electrode and a cathode electrode.

According to one or more embodiments of the present disclosure, a display device includes: a substrate; an anode electrode on the substrate; a light emitting stack on the anode electrode; a pixel defining layer on the light emitting stack and having a trench; and a cathode electrode on the light emitting stack and the pixel defining layer, wherein the anode electrode includes: a plurality of conductive (e.g., electrically conductive) layers; a protruding pattern that protrudes toward the light emitting stack from one selected from among the plurality of conductive (e.g., electrically conductive) layers; and an insulating (e.g., electrically insulating) layer around (e.g., surrounding) the protruding pattern and including silver (Ag) and nitrogen (N) (e.g., a silver compound containing nitrogen).

According to one or more embodiments of the present disclosure, a vehicle includes a display device, wherein the display device includes: a substrate; an anode electrode on the substrate; a light emitting stack on the anode electrode; a pixel defining layer on the light emitting stack and having a trench; and a cathode electrode on the light emitting stack and the pixel defining layer, and the anode electrode includes: a plurality of conductive (e.g., electrically conductive) layers; a protruding pattern that protrudes toward the light emitting stack from one selected from among the plurality of conductive (e.g., electrically conductive) layers; and an insulating (e.g., electrically insulating) layer around (e.g., surrounding) the protruding pattern and including silver (Ag) and nitrogen (N) (e.g., a silver compound containing nitrogen).

According to one or more embodiments of the present disclosure, a method for fabricating a display device includes: forming or providing a protective layer and a via layer on a substrate; forming or providing an anode electrode on the protective layer and the via layer; forming or providing a pixel defining layer on the anode electrode and the via layer; forming or providing a mask layer on the pixel defining layer and the anode electrode; forming or providing a photoresist pattern on the mask layer; forming or providing a mask pattern by removing the mask layer by utilizing the photoresist pattern as a mask; removing the photoresist pattern; forming or providing a trench in the pixel defining layer by removing the pixel defining layer by utilizing the mask pattern as another mask; removing the mask pattern; curing the substrate from which the mask pattern has been removed (or was removed); and forming or providing an insulating (e.g., electrically insulating) layer around (e.g., surrounding) a protruding pattern on the anode electrode by plasma-treating the cured substrate using N₂ gas, wherein the insulating (e.g., electrically insulating) layer includes silver (Ag) and nitrogen (N) (e.g., a silver compound containing nitrogen).

According to one or more embodiments, an electronic device includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

According to the display device, the vehicle, and the method for manufacturing the display device, the short circuit between the anode electrode and the cathode electrode may be prevented (or a degree or occurrence of the short circuit between the anode electrode and the cathode electrode may be reduced).

However, the aspects, effects, and/or embodiments of the present disclosure are not restricted to the one set forth herein. The above and other aspects, effects, and/or embodiments of the present disclosure will become more apparent to one of daily skill in the art to which the present disclosure pertains by referencing the appended claims and equivalents thereof.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings, in which:

FIG. 1 is a perspective view of a display device according to one or more embodiments;

FIG. 2 is a plan view of a display device according to one or more embodiments;

FIG. 3 is a cross-sectional view illustrating an example taken along the line I-I′ of FIG. 2;

FIG. 4 is a cross-sectional view of the display device according to one or more embodiments;

FIG. 5 is an enlarged view of area A1 of FIG. 4;

FIGS. 6-15 are process cross-sectional views illustrating a method for fabricating the display device according to one or more embodiments;

FIG. 16 is a diagram illustrating a tomography image of an anode electrode according to one or more embodiments;

FIG. 17 is an illustrative view illustrating an instrument board and a center fascia of a vehicle including display devices according to one or more embodiments;

FIG. 18 is a block diagram of an electronic device according to one or more embodiments; and

FIGS. 19 and 20 are schematic diagrams of electronic devices according to one or more embodiments.

### DETAILED DESCRIPTION

The subject matter of the present disclosure will be described more fully hereinafter with reference to the accompanying drawings, in which embodiments of the present disclosure are illustrated. The subject matter of the present disclosure may, however, be embodied in one or more suitable forms and should not be construed as being limited to one or more embodiments set forth herein, and one or more suitable changes and modifications may be made. Rather, these embodiments are provided as examples so that this disclosure will be thorough and complete and will fully convey the aspects and features of present disclosure to those skilled in the art to which the present disclosure pertains.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a layer is referred to as being “on” another layer or substrate, it may be directly on the other layer or substrate, or intervening layers may also be present therebetween. In contrast, if (e.g., when) a layer is referred to as being “directly on” another layer or substrate, there may be no intervening layers present therebetween.

The same reference numbers indicate substantially the same components throughout the specification.

In the attached drawings, the thickness of layers and regions may be exaggerated to effectively or suitably illustrate the technical contents of the present disclosure.

Although the terms “first”, “second”, and/or the like may be used herein to describe one or more suitable elements, these elements, should not be limited by these terms. These terms may be used to distinguish one element from another element. Thus, a first element discussed herein may be termed a second element without departing from teachings of one or more embodiments. The description of an element as a “first” element may not require or imply the presence of a second element or other elements. The terms “first”, “second”, and/or the like may also be used herein to differentiate different categories or sets of elements. For conciseness, the terms “first”, “second”, and/or the like may represent “first-category (or first-set)”, “second-category (or second-set)”, and/or the like, respectively.

The utilization of “may,” if (e.g., when) describing embodiments of the present disclosure, refers to “one or more embodiments of the present disclosure.”

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein, is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within +30%, +20%, +10%, or +5% of the stated value.

In the context of the present application and unless otherwise defined, the terms “use,” “using,” and “used” may be considered synonymous with the terms “utilize,” “utilizing,” and “utilized,” respectively.

The aspects and features of one or more embodiments of the present disclosure may be combined partially or totally.

As will be clearly appreciated by those skilled in the art, technically one or more suitable interactions and operations may be possible. One or more embodiments may be practiced individually or in combination.

Hereinafter, one or more embodiments will be described in more detail with reference to the accompanying drawings.

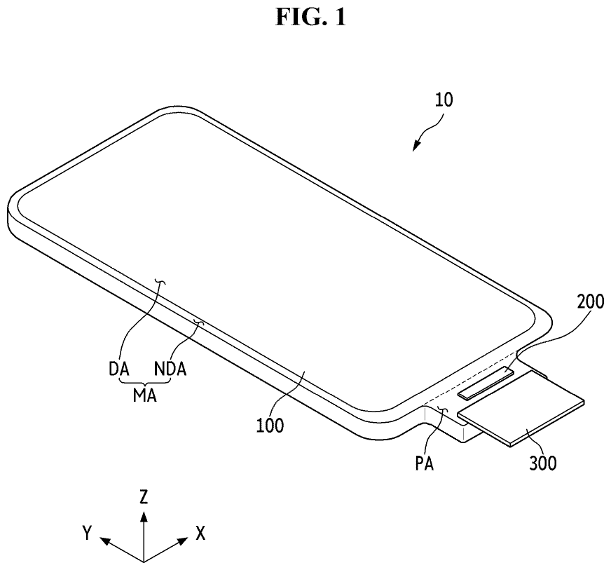

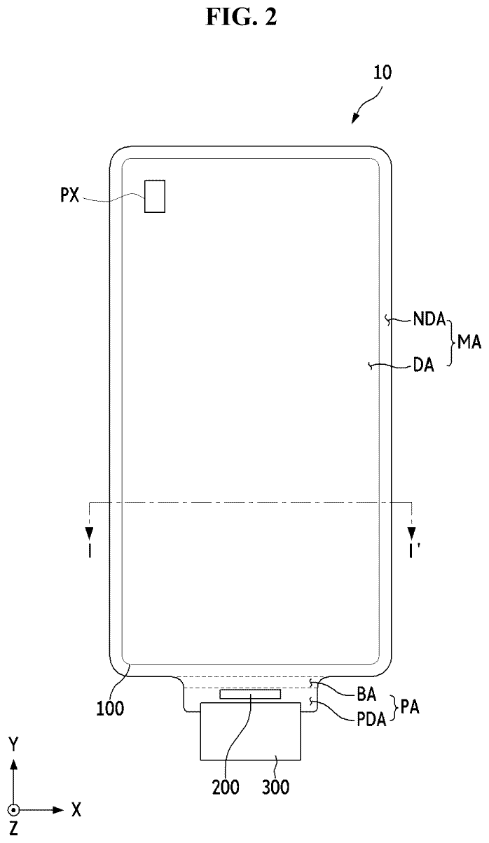

FIG. 1 is a perspective view of a display device according to one or more embodiments. FIG. 2 is a plan view of a display device according to one or more embodiments.

Referring to FIGS. 1 and 2, a display device 10 may be a device that displays a moving image and/or a still image and may be used as a display screen of each of one or more suitable products, such as televisions, laptop computers, monitors, billboards, and Internet of Things (IoT), as well as portable electronic devices, such as mobile phones, smartphones, tablet personal computers (PCs), smartwatches, watch phones, mobile communication terminals, electronic organizers, electronic books, portable multimedia players (PMPs), navigation devices, and ultra mobile PCs (UMPCs). The display device 10 may be any one selected from among an organic light emitting diode display device, a liquid crystal display device, a plasma display device, a field emission display device, an electrophoretic display device, an electrowetting display device, a quantum dot light emitting display device, and a micro LED display device. Hereinafter, it is mainly or predominantly described that the display device 10 is the organic light emitting diode display device, but embodiments of the present disclosure are not limited thereto.

The display device 10 according to one or more embodiments may include a display panel 100, a display driving circuit 200, and a circuit board 300.

The display panel 100 may include a main area MA and a protruding area PA that protrudes from one side of the main area MA.

The main area MA may be in a rectangular (e.g., substantially rectangular) plane having short sides in a first direction (X-axis direction) and long sides in a second direction (Y-axis direction) that crosses (e.g., intersects) the first direction (X-axis direction). A corner where the short side in the first direction (X-axis direction) and the long side in the second direction (Y-axis direction) meet may be rounded to have a set or predetermined curvature or may be at a right angle. The planar (e.g., substantially planar) shape of the display device 10 is not limited to a quadrangular (e.g., substantially quadrangular) shape, and may be in other polygonal (e.g., substantially polygonal), circular (e.g., substantially circular), or oval (e.g., substantially oval) shapes. The main area MA may be formed or provided to be flat (e.g., substantially flat), but embodiments of the present disclosure are not limited thereto, and may include curved portions at left end and/or right end. In this case, the curved portion may have a constant (e.g., substantially constant) curvature or a changing curvature.

The main area MA may include a display area DA in which a plurality of pixels PX are formed or provided to display an image, and a non-display area NDA, which is a peripheral area of the display area DA.

In the display area DA, not only the pixels PX but also scan lines, data lines, and power lines connected to the pixels PX may be arranged or provided. If (e.g., when) the main area MA includes the curved portion, the display area DA may be on the curved portion. In this case, the image of the display panel 100 may be viewed even on the curved portion.

The non-display area NDA may be defined as an area from the outside of the display area DA to an edge of the display panel 100. A scan driver to apply scan signals to the scan lines and link lines that connect the data lines and the display driving circuit 200 may be arranged or provided in the non-display area NDA.

The protruding area PA may protrude from one side of the main area MA. For example, the protruding area PA may protrude from a lower side of the main area MA as illustrated in FIG. 2. A length of the protruding area PA in the first direction (X-axis direction) may be smaller than a length of the main area MA in the first direction (X-axis direction).

The protruding area PA may include a bending area BA and a pad area PDA. In this case, the pad area PDA may be on one side of the bending area BA, and the main area MA may be on the other side of the bending area BA. For example, the pad area PDA may be on a lower side of the bending area BA, and the main area MA may be on an upper side of the bending area BA.

The display panel 100 may be flexibly formed or provided to be curved, bent, folded, and/or rolled. Therefore, the display panel 100 may be bent in a thickness direction (e.g., a third direction Z) in the bending area BA. In this case, before the display panel 100 is bent, one surface of the pad area PDA of the display panel 100 may face upward, but after the display panel 100 is bent, one surface of the pad area PDA of the display panel 100 may face downward. As a result, because the pad area PDA is on the lower side of the main area MA, the pad area PDA may overlap the main area MA.

Pads electrically connected to the display driving circuit 200 and the circuit board 300 may be in the pad area PDA of the display panel 100.

The display driving circuit 200 may be to output signals and voltages to drive the display panel 100. For example, the display driving circuit 200 may supply data voltages to the data lines. In one or more embodiments, the display driving circuit 200 may be to supply power voltage to the power line and scan control signals to the scan driver. The display driving circuit 200 may be formed or provided as an integrated circuit (IC) and be attached onto the display panel 100 in the pad area PDA by using a chip on glass (COG) method, a chip on plastic (COP) method, and/or an ultrasonic bonding method, but embodiments of the present disclosure are not limited thereto. For example, the display driving circuit 200 may be mounted on the circuit board 300.

The pads may include display pads electrically connected to the display driving circuit 200 and touch pads electrically connected to the touch lines.

The circuit board 300 may be attached onto the pads by using an anisotropic conductive (e.g., electrically conductive) film. Accordingly, the lead lines of the circuit board 300 may be electrically connected to the pads. The circuit board 300 may be a flexible film, such as a flexible printed circuit board, a printed circuit board, or a chip on film.

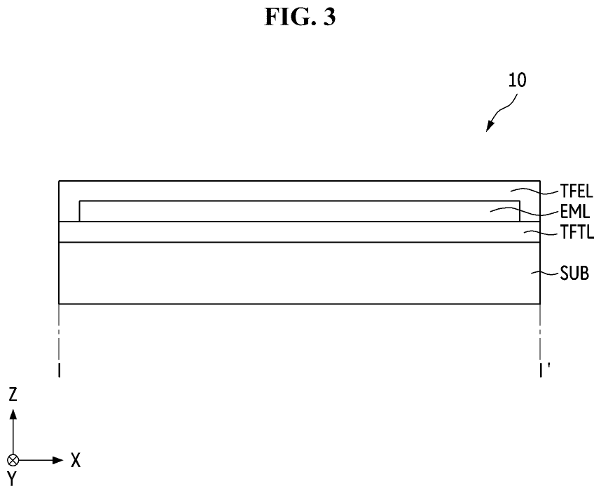

FIG. 3 is a cross-sectional view illustrating an example taken along the line I-I′ of FIG. 2.

Referring to FIG. 3, the display panel 100 may include a substrate SUB, a thin film transistor layer TFTL, a light emitting element layer EML, and a thin film encapsulation layer TFEL on the substrate SUB.

The substrate SUB may be made of an insulating (e.g., electrically insulating) material (e.g., insulator), such as glass, quartz, and/or a polymer resin. Examples of the polymer material may include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), and/or a (e.g., any suitable) combination thereof. In one or more embodiments, the substrate SUB may also include a metal material.

The substrate SUB may be a rigid substrate or a flexible substrate that may be bent, folded, and/or rolled. If (e.g., when) the substrate SUB is the flexible substrate, the substrate SUB may be of polyimide (PI), but embodiments of the present disclosure are not limited thereto.

The thin film transistor layer TFTL may be on the substrate SUB. In the thin film transistor layer TFTL, scan lines, data lines, power lines, scan control lines, and routing lines that connect the pads and the data lines as well as thin film transistors of each of the pixels may be formed or provided. Each of the thin film transistors may include a gate electrode, a semiconductor layer, a source electrode, and a drain electrode.

The thin film transistor layer TFTL may be in the display area DA and the non-display area NDA. For example, the thin film transistors of each of the pixels, the scan lines, the data lines, and the power lines of the thin film transistor layer TFTL may be in the display area DA. The scan control lines and link lines of the thin film transistor layer TFTL may be in the non-display area NDA.

The light emitting element layer EML may be on the thin film transistor layer TFTL. The light emitting element layer EML may include a light emitting element and a pixel defining layer. The light emitting element layer EML may include an organic material. In this case, the light emitting layer may include a hole transporting layer, an organic light emitting layer, and an electron transporting layer. If (e.g., when) a set or predetermined voltage is applied to an anode electrode and a cathode voltage is applied to a cathode electrode through the thin film transistor of the thin film transistor layer TFTL, holes and electrons may move to the organic light emitting layer through the hole transporting layer and the electron transporting layer, respectively and may be bonded to each other in the organic light emitting layer to emit light.

The thin film encapsulation layer TFEL may be on the light emitting element layer EML. The thin film encapsulation layer TFEL may act or serve to prevent oxygen and/or moisture from permeating into the light emitting element layer EML (or to reduce a degree to or occurrence of which oxygen and/or moisture permeate into the light emitting element layer EML). To this end, the thin film encapsulation layer TFEL may include at least one inorganic layer. In one or more embodiments, the thin film encapsulation layer TFEL may act or serve to protect the light emitting element layer EML from foreign substances, such as dust. To this end, the thin film encapsulation layer TFEL may include at least one organic layer.

The thin film encapsulation layer TFEL may be in both (e.g., simultaneously) the display area DA and the non-display area NDA. For example, the thin film encapsulation layer TFEL may be to cover the light emitting element layer EML of the display area DA and the non-display area NDA and cover the thin film transistor layer TFTL of the non-display area NDA.

A cover window may be additionally arranged or provided on the thin film encapsulation layer TFEL, and a touch sensing layer may be additionally arranged or provided between the thin film encapsulation layer TFEL and the cover window. In this case, the cover window may be attached to a lower layer by a transparent (e.g., substantially transparent) adhesive material, such as an optically clear adhesive (OCA) film.

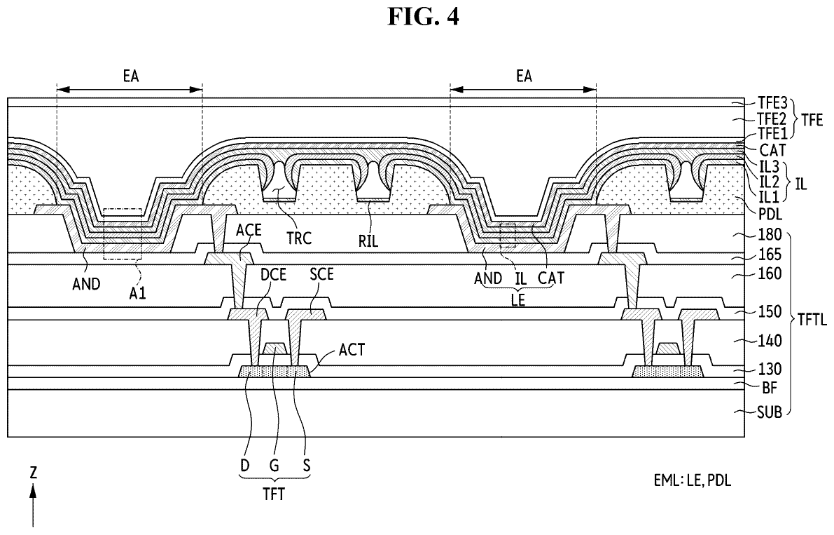

FIG. 4 is a cross-sectional view of the display device according to one or more embodiments.

The thin film transistor layer TFTL may be on the substrate SUB of the display device 10. The thin film transistor layer TFTL may include a thin film transistor TFT, a buffer layer BF, a gate insulating layer 130, an interlayer insulating layer 140, a first protective layer 150, a planarization layer 160, a second protective layer 165, and a via layer 180.

A buffer layer BF may be on the substrate SUB. The buffer layer BF may be on the substrate SUB to protect the thin film transistors TFT and the organic light emitting layer of the light emitting element layer EML from moisture permeating through the substrate SUB (or to reduce a degree to or occurrence of which moisture permeates into the thin film transistors TFT and the organic light emitting layer of the light emitting element layer EML through the substate SUB), which is vulnerable to moisture permeation. The buffer layer BF may include a plurality of inorganic layers that are alternately stacked. For example, the buffer layer BF may be formed or provided as a multi-film in which one or more inorganic layers of a silicon nitride layer, a silicon oxynitride layer, a silicon oxide layer, a titanium oxide layer, and an aluminum oxide layer are alternately stacked. In one or more embodiments, the buffer layer BF may not be provided.

An active layer ACT may be on the buffer layer BF. The active layer ACT may include polycrystalline silicon, single crystal silicon, low-temperature polycrystalline silicon, amorphous (e.g., non-crystalline) silicon, and/or an oxide semiconductor. For example, the oxide semiconductor may include a binary compound (ABx), a ternary compound (ABxCy), and/or a quaternary compound (ABxCyDz) containing indium (In), zinc (Zn), gallium (Ga), tin (Sn), titanium (Ti), aluminum (Al), hafnium (Hf), zirconium (Zr), magnesium (Mg), and/or the like. For example, the active layer ACT may include ITZO (oxide including indium, tin, and zinc) and/or IGZO (oxide including indium, gallium, and zinc).

A gate insulating layer 130 may be on the active layer ACT. The gate insulating layer 130 may be formed or provided as an inorganic film, for example, a silicon nitride layer, a silicon oxynitride layer, a silicon oxide layer, a titanium oxide layer, and/or an aluminum oxide layer.

A gate electrode G may be on the gate insulating layer 130. For example, the gate electrode G may be on the gate insulating layer 130 so as to overlap the active layer ACT. A channel region may be in an area of the active layer ACT that overlaps the gate electrode G. A drain electrode D and a source electrode S may be arranged or provided, respectively, on both (e.g., simultaneously) sides (e.g., two opposing sides) of the channel region of the active layer ACT. The thin film transistor TFT as described in one or more embodiments may include a gate electrode G, a drain electrode D, and a source electrode S. The gate electrode G may be formed or provided as a single layer or a multilayer made of any one selected from among molybdenum (Mo), aluminum (Al), chromium (Cr), gold (Au), titanium (Ti), nickel (Ni), neodymium (Nd), and copper (Cu), or an (e.g., any suitable) alloy thereof.

An interlayer insulating layer 140 may be on the gate electrode G. The interlayer insulating layer 140 may be formed or provided as an inorganic layer, for example, a silicon nitride layer, a silicon oxynitride layer, a silicon oxide layer, a titanium oxide layer, and/or an aluminum oxide layer.

A drain connection electrode DCE and a source connection electrode SCE may be on the interlayer insulating layer 140. The drain connection electrode DCE may be connected to the drain electrode D of the active layer ACT through a contact hole that penetrates through the interlayer insulating layer 140 and the gate insulating layer 130. The source connection electrode SCE may be connected to the source electrode S of the active layer ACT through a contact hole that penetrates through the interlayer insulating layer 140 and the gate insulating layer 130. The drain connection electrode DCE may be formed or provided as a single layer or a multilayer made of any one selected from among molybdenum (Mo), aluminum (Al), chromium (Cr), gold (Au), titanium (Ti), nickel (Ni), neodymium (Nd), and copper (Cu), or an (e.g., any suitable) alloy thereof. The source connection electrode SCE may be made of substantially the same materials as the drain connection electrode as described in one or more embodiments.

A first protective layer 150 may be on the drain connection electrode DCE and the source connection electrode SCE. The first protective layer 150 may be formed or provided as an inorganic layer, for example, a silicon nitride layer, a silicon oxynitride layer, a silicon oxide layer, a titanium oxide layer, and/or an aluminum oxide layer.

A planarization layer 160 may be on the first protective layer 150. The planarization layer 160 may be formed or provided as an organic layer made of an acrylic resin, an epoxy resin, a phenolic resin, a polyamide resin, and/or a polyimide resin.

An anode connection electrode ACE may be on the planarization layer 160. The anode connection electrode ACE may be connected to the drain connection electrode DCE through a contact hole that penetrates through the planarization layer 160 and the first protective layer 150.

A second protective layer 165 may be on the anode connection electrode ACE. The second protective layer 165 may be formed or provided as an inorganic layer, for example, a silicon nitride layer, a silicon oxynitride layer, a silicon oxide layer, a titanium oxide layer, and/or an aluminum oxide layer.

A via layer 180 may be on the second protective layer 165. The via layer 180 may be of an organic material, for example, an acrylic resin, an epoxy resin, a phenolic resin, a polyamide resin, a polyimide resin, and/or the like.

A light emitting element layer EML may be on the thin film transistor layer TFTL. For example, the light emitting element layer EML may be on the second protective layer 165 and the via layer 180. The light emitting element layer EML may include a light emitting element LE and a pixel defining layer PDL. The light emitting element LE may include an anode electrode AND, a light emitting stack IL, and a cathode electrode CAT.

The anode electrode AND may be on the second protective layer 165 and the via layer 180. The anode electrode AND may be connected to the anode connection electrode ACE through a contact hole that penetrates through the via layer 180 and the second protective layer 165. The anode electrode AND may include a reflective (e.g., substantially reflective) material. In one or more embodiments, the reflective (e.g., substantially reflective) material may include one or more reflective films selected from the group consisting of silver (Ag), magnesium (Mg), chromium (Cr), gold (Au), platinum (Pt), nickel (Ni), copper (Cu), tungsten (W), and aluminum (Al), and a transparent electrode and/or a semitransparent electrode on the reflective film. In one or more embodiments, the transparent electrode and/or the semitransparent electrode may include one or more selected from the group consisting of indium tin oxide (ITO), indium zinc oxide (IZO), zinc oxide (ZnO), indium oxide (In₂O₃), indium gallium oxide (IGO), and aluminum zinc oxide (AZO).

The pixel defining layer PDL may define a light emitting area of the pixel. The light emitting area EA may be defined as an area in which the anode electrode AND, the light emitting stack IL, and the cathode electrode CAT are sequentially stacked in the pixel to emit light. The pixel defining layer PDL may be on the via layer 180 to cover an edge of the anode electrode AND. The pixel defining layer PDL may include trenches TRC. For example, the pixel defining layer PDL may include trenches TRC having a recessed shape in a thickness direction of the pixel defining layer PDL (e.g., in a direction opposite to the third direction Z). The pixel defining layer PDL may be formed or provided as an organic layer made of an acryl resin, an epoxy resin, a phenolic resin, a polyamide resin, a polyimide resin, and/or the like.

The light emitting stack IL may be on the anode electrode AND and the pixel defining layer PDL. The light emitting stack IL may include a plurality of stack layers. It is illustrated in FIG. 4 that the light emitting stack IL may have a three-tandem structure including a first stack layer IL1, a second stack layer IL2, and a third stack layer IL3, but embodiments of the present disclosure are not limited thereto. For example, the light emitting stack IL may have a two-tandem structure including two stack layers.

In the three-tandem structure, the light emitting stack IL may have a tandem structure including a plurality of stack layers IL1, IL2, and IL3 that are to emit different lights. For example, the light emitting stack IL may include a first stack layer IL1 that emits light of a first color (e.g., red light or light in a red wavelength band), a second stack layer IL2 that emits light of a second color (e.g., green light or light in a green wavelength band), and a third stack layer IL3 that emits light of a third color (e.g., blue light or light in a blue wavelength band). The first stack layer IL1, the second stack layer IL2, and the third stack layer IL3 may be sequentially stacked.

The first stack layer IL1 may have a structure in which a first hole transporting layer, a first organic light emitting layer that emits light of a first color, and a first electron transporting layer are sequentially stacked. The second stack layer IL2 may have a structure in which a second hole transporting layer, a second organic light emitting layer that emits light of a second color, and a second electron transporting layer are sequentially stacked. The third stack layer IL3 may have a structure in which a third hole transporting layer, a third organic light emitting layer that emits light of a third color, and a third electron transporting layer are sequentially stacked.

A first charge generation layer to supply charges to the second stack layer IL2 and supply electrons to the first stack layer IL1 may be between the first stack layer IL1 and the second stack layer IL2. The first charge generation layer may include a negative type (kind) (N-type (kind)) charge generation layer that supplies electrons to the first stack layer IL1 and a positive type (kind) (P-type (kind)) charge generation layer that supplies holes to the second stack layer IL2. The N-type (kind) charge generation layer may include a dopant of a metallic material.

A second charge generation layer to supply charges to the third stack layer IL3 and supply electrons to the second stack layer IL2 may be between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be on the anode electrodes AND and the pixel defining layer PDL. A residual stack layer RIL made of substantially the same material as the first stack layer IL1 may be on a bottom surface of each trench TRC. Due to the trench TRC, the first stack layer IL1 may be disconnected between the pixels PX adjacent to each other. The second stack layer IL2 may be on the first stack layer IL1. Due to the trench TRC, the second stack layer IL2 may be disconnected between the pixels PX adjacent to each other. The third stack layer IL3 may be on the second stack layer IL2. The third stack layer IL3 may not be disconnected by the trench TRC and may be to cover the second stack layer IL2 in each of the trenches TRC. For example, in the three-tandem structure, each of the plurality of trenches TRC may be a structure to disconnect the first stack layer IL1, the second stack layer IL2, the first charge generation layer, and the second charge generation layer of the light emitting element layer EML between the pixels PX adjacent to each other.

In one or more embodiments, in the two-tandem structure, each of the plurality of trenches TRC may be a structure to disconnect the charge generation layer between a lower stack layer and an upper stack layer.

The cathode electrode CAT may be on the third stack layer IL3. The cathode electrode CAT may be on the third stack layer IL3 in each of the plurality of trenches TRC. The cathode electrode CAT may be of a transparent (e.g., substantially transparent) conductive (e.g., electrically conductive) material (TCO), such as ITO and/or IZO, capable of transmitting light, or a semi-transmissive conductive (e.g., electrically conductive) material, such as magnesium (Mg), silver (Ag), or an alloy of magnesium (Mg) and silver (Ag). If (e.g., when) the cathode electrode CAT is of the semi-transmissive conductive (e.g., electrically conductive) material, light emitting efficiency in each of the pixels PX may be increased or enhanced by a micro cavity.

An encapsulation layer TFEL may be on the cathode electrode CAT. The encapsulation layer TFEL may include at least one inorganic layer to prevent oxygen and/or moisture from permeating into the light emitting element layer EML (or to reduce a degree to or occurrence of which oxygen and/or moisture permeates into the light emitting element layer EML). In one or more embodiments, the encapsulation layer TFEL may include at least one organic layer to protect the light emitting element layer EML from foreign substances, such as dust. For example, the encapsulation layer TFEL may include a first inorganic layer TFE1 on the cathode electrode CAT, an organic layer TFE2 on the first inorganic layer TFE1, and a second inorganic layer TFE3 on the organic layer TFE2. The first inorganic layer TFE1 and the second inorganic layer TFE3 may be formed or provided as a silicon nitride layer, a silicon oxynitride layer, a silicon oxide layer, a titanium oxide layer, or an aluminum oxide layer, but embodiments of the present disclosure are not limited thereto. The organic layer TFE2 may be of an acrylic resin, an epoxy resin, a phenolic resin, a polyamide resin, and/or a polyimide resin, but embodiments of the present disclosure are not limited thereto.

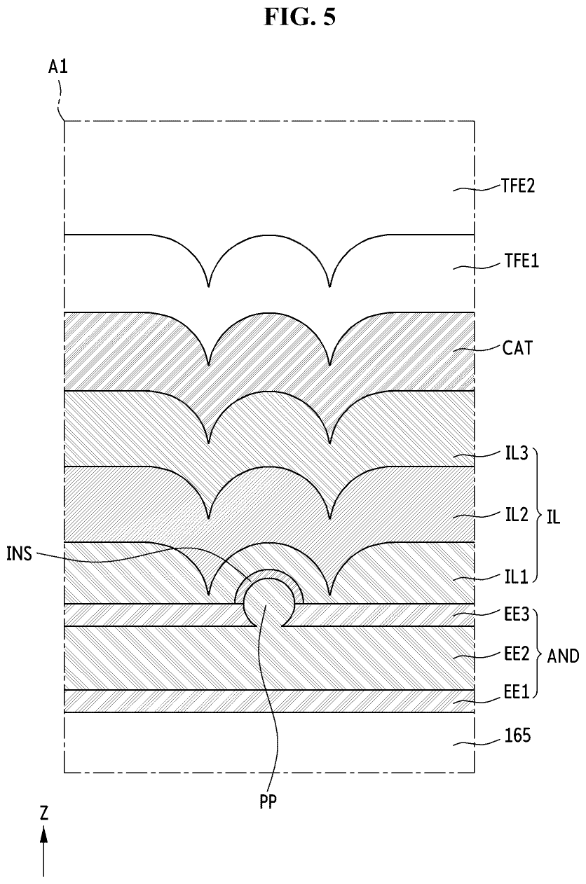

FIG. 5 is an enlarged view of area A1 of FIG. 4.

As illustrated in FIG. 5, the anode electrode AND may include a plurality of conductive layers EE1, EE2, and EE3 sequentially stacked along the third direction Z. For example, the anode electrode may include a first conductive layer EE1, a second conductive layer EE2, and a third conductive layer EE3.

The first conductive layer EE1 may be on the second protective layer 165 and the via layer 180. The first conductive layer EE1 may include a transparent electrode and/or a semitransparent electrode. For example, the first conductive layer EE1 may include one or more selected from the group consisting of indium tin oxide (ITO), indium zinc oxide (IZO), zinc oxide (ZnO), indium oxide (In203), indium gallium oxide (IGO), and aluminum zinc oxide (AZO). According to one or more embodiments, the first conductive layer EE1 may include ITO.

The second conductive layer EE2 may be on the first conductive layer EE1. For example, the second conductive layer EE2 may be between the first conductive layer EE1 and the third conductive layer EE3. A thickness of the second conductive layer EE2 may be greater than a thickness of the first conductive layer EE1. In one or more embodiments, the thickness of the second conductive layer EE2 may be greater than a thickness of the third conductive layer EE3. The second conductive layer EE2 may include one or more selected from the group consisting of silver (Ag), magnesium (Mg), chromium (Cr), gold (Au), platinum (Pt), nickel (Ni), copper (Cu), tungsten (W), and aluminum (Al). According to one or more embodiments, the second conductive layer EE2 may include silver (Ag).

The third conductive layer EE3 may be on the second conductive layer EE2. The third conductive layer EE3 may include a transparent electrode and/or a semitransparent electrode. For example, the third conductive layer EE3 may include one or more selected from the group consisting of indium tin oxide (ITO), indium zinc oxide (IZO), zinc oxide (ZnO), indium oxide (In203), indium gallium oxide (IGO), and aluminum zinc oxide (AZO). According to one or more embodiments, the third conductive layer EE3 may include ITO.

According to one or more embodiments, the anode electrode AND may further include a protruding pattern (PP; or eruption pattern, or particle) and an insulating layer INS. The protruding pattern PP may protrude from the second conductive layer EE2. For example, the protruding pattern PP may protrude from the second conductive layer EE2 and be exposed to the outside of the third conductive layer EE3 through a pin hole in the third conductive layer EE3 thereon. The protruding pattern PP may have, for example, a circular (e.g., substantially circular) cross-sectional shape or an elliptical (e.g., substantially elliptical) cross-sectional shape. However, the shape of the protruding pattern PP is not limited thereto.

The insulating layer INS may be on the protruding pattern PP exposed to the outside of the third conductive layer EE3. The insulating layer INS may be between the protruding pattern PP and the light emitting stack IL. For example, the insulating layer INS may be around (e.g., surround) the protruding pattern PP on the third conductive layer EE3. The insulating layer INS may be in contact (or in direct contact) with the protruding pattern PP and the third conductive layer EE3, respectively. For example, the insulating layer INS may be an oxide layer and/or an oxynitride layer on a surface of the protruding pattern PP. A thickness of the insulating layer INS may be, for example, greater than or equal to about 50 Å. In one or more embodiments, the thickness of the insulating layer INS may be, for example, greater than or equal to about 100 Å. According to one or more embodiments, the protruding pattern PP may be insulated by the insulating layer INS. Accordingly, short circuit between the protruding pattern PP of the anode electrode AND and the cathode electrode CAT may be prevented (or a degree or occurrence of short circuit between the protruding pattern PP of the anode electrode AND and the cathode electrode CAT may be reduced).

The light emitting stack IL may be on the protruding pattern PP. In this case, the first stack layer IL1, the second stack layer IL2, and the third stack layer IL3 that overlap the protruding pattern PP may have a curved shape according to the shape of the protruding pattern PP. In one or more embodiments, the first inorganic layer TFE1, the organic layer TFE2, and the second inorganic layer TFE3 of the encapsulation layer TFE that overlap the protruding pattern PP may each have a curved shape.

If (e.g., when) the second conductive layer EE2 of the anode electrode AND includes silver (Ag), the protruding pattern PP may include at least one selected from among silver oxide (AgO) and silver fluoride (AgF), and the insulating layer INS (having silver (Ag) and nitrogen (N), e.g., a silver compound containing nitrogen) may include or be at least one selected from among silver nitride (AgsN) and silver nitrate (AgNO₃). The insulating layer INS may have specific resistance of about 615 nΩcm. For example, if (e.g., when) the insulating layer INS includes silver nitrate (AgNO₃), the insulating layer INS may have specific resistance of about 615 nΩcm at 20 degrees Celsius (° C.).

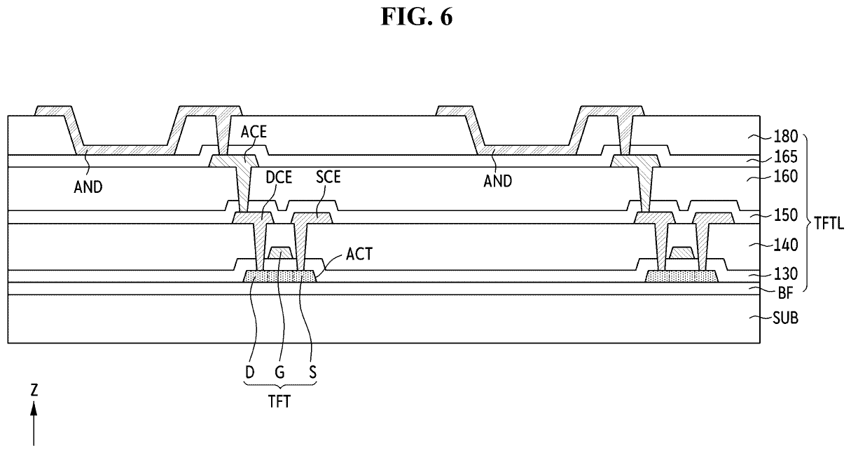

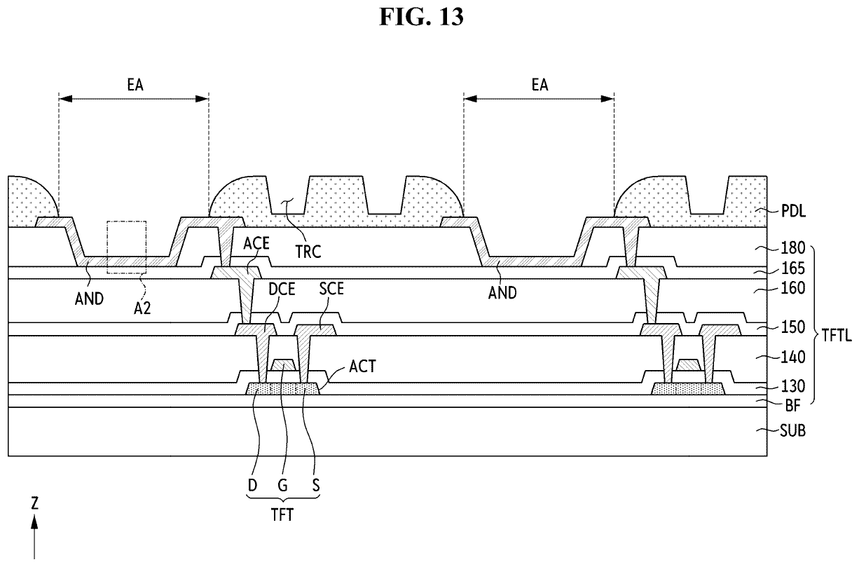

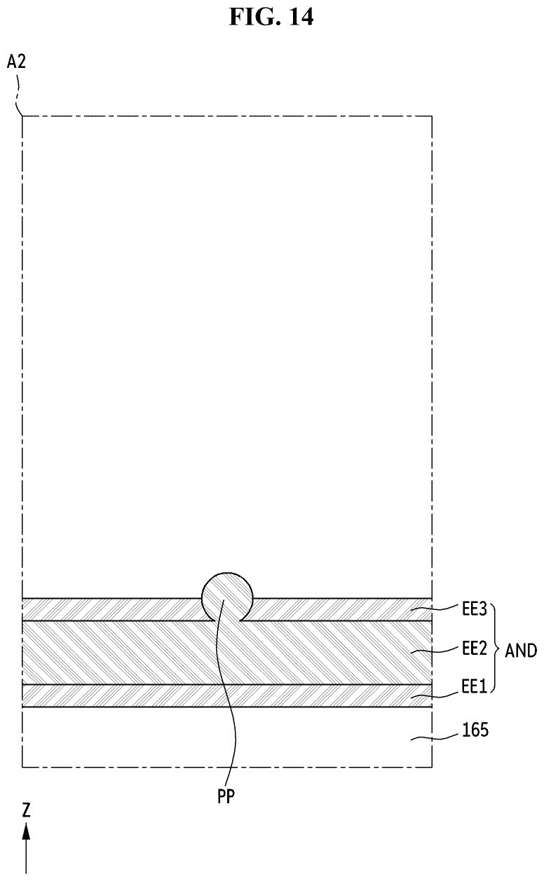

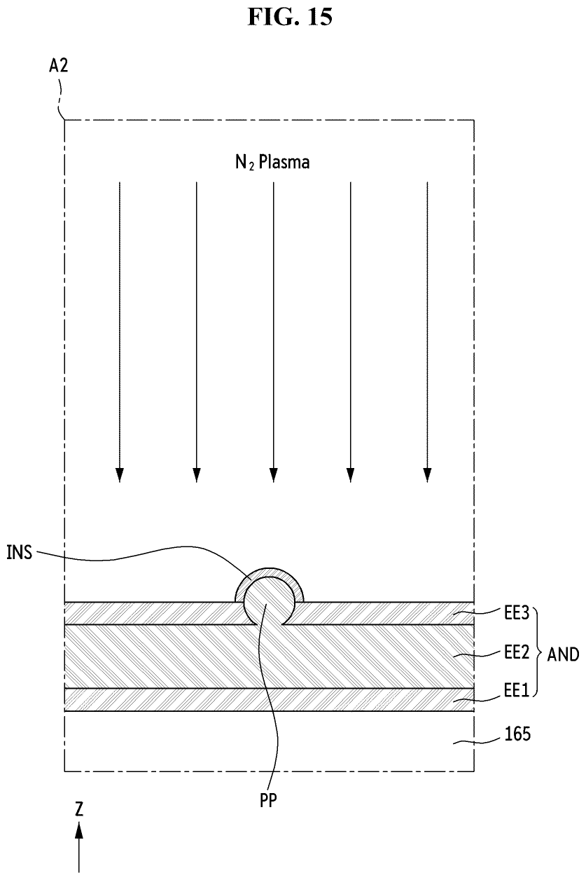

FIGS. 6 to 15 are process cross-sectional views illustrating a method for fabricating the display device according to one or more embodiments. In one or more embodiments, FIGS. 14 and 15 are enlarged views of area A2 of FIG. 13.

As illustrated in FIG. 6, after a thin film transistor layer TFTL is formed or provided on a substrate SUB, an anode electrode AND may be formed or provided on a second protective layer 165 and a via layer 180 of the thin film transistor layer TFTL. For example, after the second protective layer 165 is formed or provided, the via layer 180 may be formed or provided on the second protective layer 165, and the anode electrode AND may be formed or provided on the second protective layer 165 and the via layer 180. In one or more embodiments, the anode electrode AND may include the first conductive layer EE1, the second conductive layer EE2, and the third conductive layer EE3 as described in one or more embodiments.

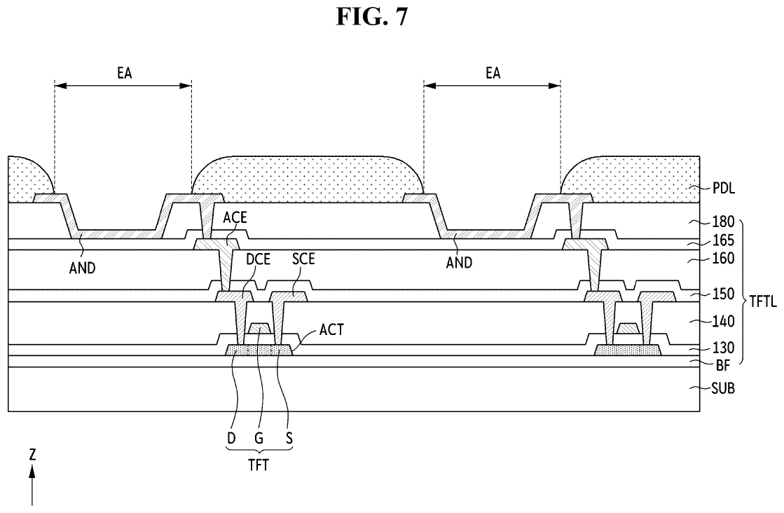

Next, as illustrated in FIG. 7, a pixel defining layer PDL that defines a light emitting area EA may be arranged or provided on the via layer 180.

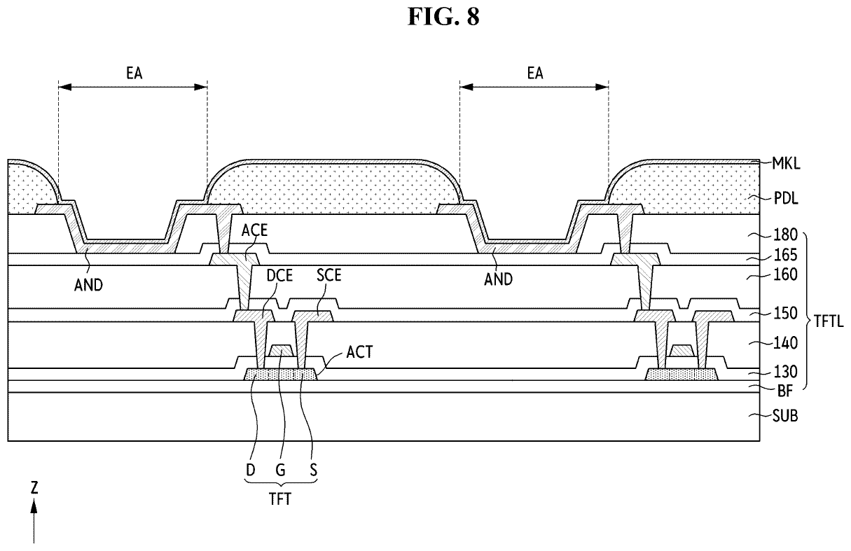

Next, as illustrated in FIG. 8, a mask layer MKL may be formed or provided on the pixel defining layer PDL and the anode electrode AND. The mask layer MKL may include, for example, IGZO (oxide including indium, gallium, and zinc).

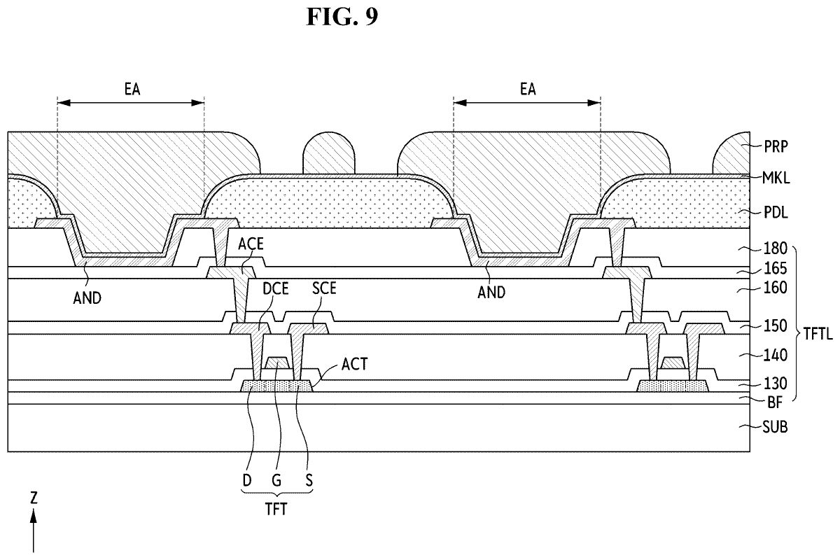

Thereafter, as illustrated in FIG. 9, a photoresist pattern PRP may be formed or provided on the mask layer MKL. The photoresist pattern PRP may be arranged or provided on the mask layer MKL so as to overlap an area excluding, for example, an area where a trench TRC is to be formed or provided.

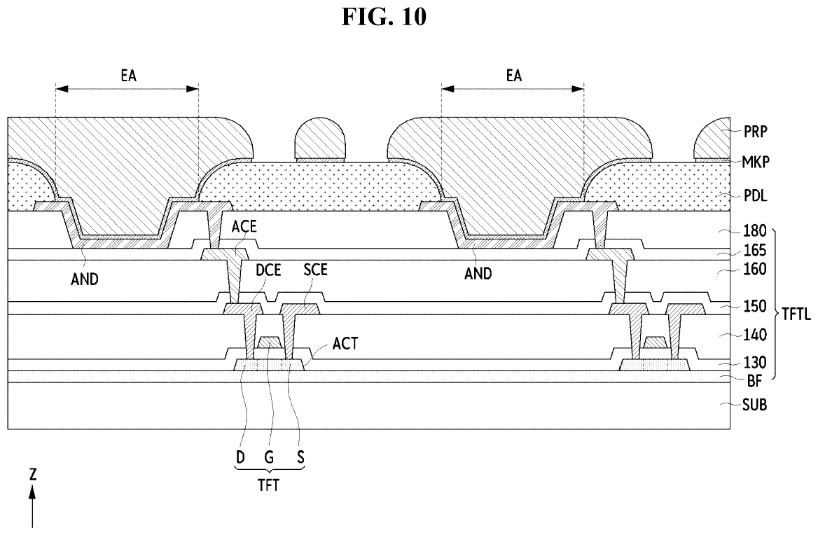

Next, as illustrated in FIG. 10, a mask pattern MKP may be formed or provided by patterning the mask layer MKL by utilizing the photoresist pattern PRP as a mask. For example, the mask pattern MKP may be formed or provided by selectively removing the mask layer MKL that is not covered by the photoresist pattern PRP. For example, the mask pattern MKP may be formed or provided between the photoresist pattern PRP and the pixel defining layer PDL, and between the photoresist pattern PRP and the anode electrode AND.

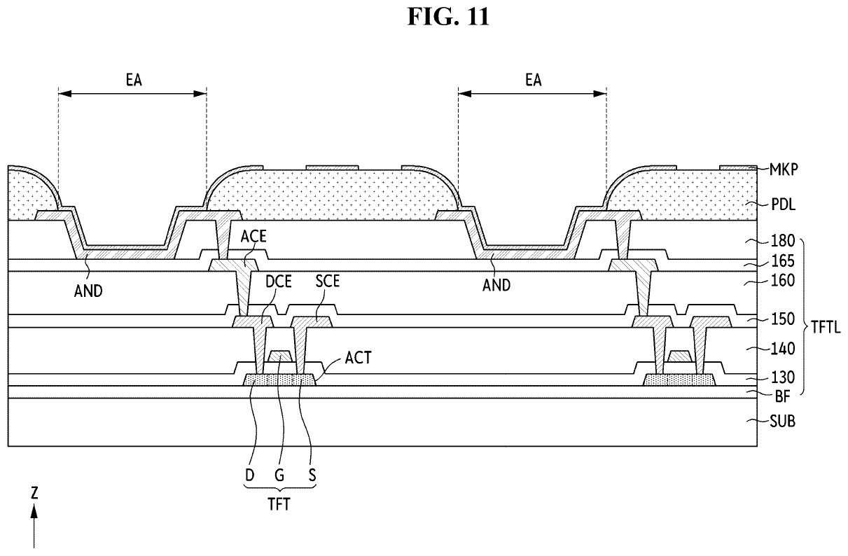

Next, as illustrated in FIG. 11, the photoresist pattern PRP may be removed.

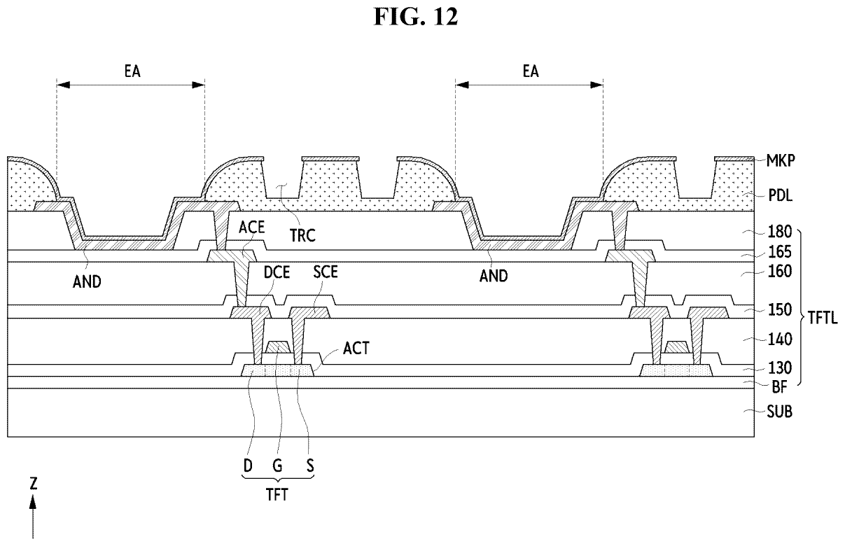

Thereafter, as illustrated in FIG. 12, a trench TRC may be formed or provided in the pixel defining layer PDL by patterning the pixel defining layer PDL by utilizing the mask pattern MKP as a mask (e.g., a hard mask). For example, the trench TRC may be formed or provided by selectively removing the pixel defining layer PDL that is not covered by the mask pattern MKP. According to one or more embodiments, the pixel defining layer PDL may be removed by an ashing process.

Next, as illustrated in FIG. 13, the mask pattern MKP may be removed. For example, the mask pattern MKP may be removed by a wet etching process.

Thereafter, a curing process (e.g., a heat treatment process) may be performed to alleviate defects (or reduce a degree or occurrence of defects) that may occur in subsequent processes. For example, the substrate SUB from which the mask pattern MKP has been removed (or was removed), as illustrated in FIG. 13, may be heat-treated at a temperature of about 270 degrees Celsius (C). In one or more embodiments, as illustrated in FIG. 14, a protruding pattern PP may be on the anode electrode AND by the heat during the curing process. For example, because the third conductive layer EE3 made of ITO may include a pin hole, the silver (Ag) component of the second conductive layer EE2 (e.g., the second conductive layer EE2 including silver (Ag)) may react with external oxygen and/or fluorine through the pin hole of the third conductive layer EE3. Then, because the second conductive layer EE2 may swell and protrude outward through the pin hole due to a thermal stress applied during the reaction and/or curing process, such a protruding portion may be the protruding pattern PP. If (e.g., when) a size of this protruding pattern PP is large, the cathode electrode CAT formed or provided during the subsequent process and the protruding pattern PP may come into contact with each other. In this case, a short circuit problem may occur where the anode electrode AND and the cathode electrode CAT are connected to each other through the protruding pattern PP.

In order to solve the problem as described in one or more embodiments, according to one or more embodiments, a plasma treatment process as illustrated in FIG. 15 may be performed. For example, after the curing process, plasma treatment of the substrate SUB using nitrogen gas (e.g., N₂) may be performed, as illustrated in FIG. 15. As plasma treatment methods, plasma etching (PE), reactive ion etching (RIE), and/or inductively coupled plasma (ICP) may be used. In addition to the N₂ gas as described in one or more embodiments, the gas used in the plasma treatment may be a mixed gas that further contains fluorine (F) and/or chlorine (CI).

By the plasma treatment process as described in one or more embodiments, an insulating layer INS may be formed or provided on the protruding pattern PP. The insulating layer INS may be around (e.g., surround) the surface of the protruding pattern PP exposed to the outside of the anode electrode AND. The insulating layer INS (having silver (Ag) and nitrogen (N), e.g., a silver compound containing nitrogen) may include or be silver nitride (AgsN) and/or silver nitrate (AgNO₃). For example, if (e.g., when) the protruding pattern PP includes silver (Ag), the insulating layer INS (e.g., the insulating layer INS including silver nitride (AgsN)) may be formed or provided on the surface of the protruding pattern PP by plasma treatment by using the N₂ gas as described in one or more embodiments. In one or more embodiments, if (e.g., when) the protruding pattern PP includes silver fluoride (AgF), the insulating layer INS (e.g., the insulating layer INS including silver nitride (AgsN)) may be formed or provided on the surface of the protruding pattern PP by replacing silver fluoride (AgF) with silver nitride (AgsN) through the plasma treatment by using the N₂ gas as described in one or more embodiments. For example, after the curing process, the heat treatment may cause a protruding pattern PP to form on the anode electrode AND due to thermal stress. This protruding pattern may lead to short circuits if (e.g., when) it contacts the cathode electrode CAT. To address this issue, a plasma treatment process that utilizes nitrogen gas may be performed. This process may form or provide an insulating layer INS (e.g., a silver compound containing nitrogen) on the protruding pattern, which may include materials, such as silver nitride (Ag₃N) and/or silver nitrate (AgNO₃). The insulating layer may be around (e.g., surround) the protruding pattern, preventing or protecting it from making electrical contact with the cathode electrode. The plasma treatment may ensure or provide that the insulating layer is effectively or suitably formed or provided, enhancing the reliability and performance of the display device by preventing short circuits (or by reducing a degree or occurrence of short circuits).

Thereafter, as illustrated in FIG. 4, a light emitting stack IL, a cathode electrode CAT, and an encapsulation layer TFE may be sequentially formed or provided on the anode electrode AND. In this case, the first stack layer IL1 and the second stack layer IL2 may be disconnected by the trench TRC of the pixel defining layer PDL.

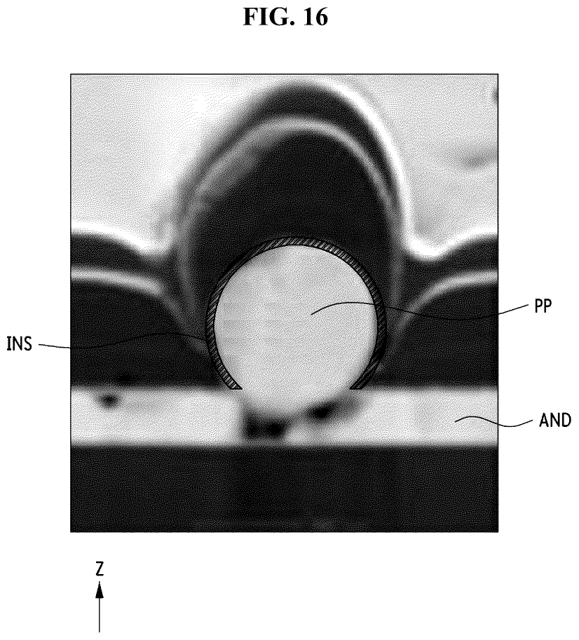

FIG. 16 is a diagram illustrating a tomography image of an anode electrode according to one or more embodiments.

As illustrated in FIG. 16, an insulating layer INS may be on the protruding pattern PP that protrudes from the anode electrode AND. For example, the insulating layer INS may be on the surface of the protruding pattern PP to be around (e.g., surround) the protruding pattern PP.

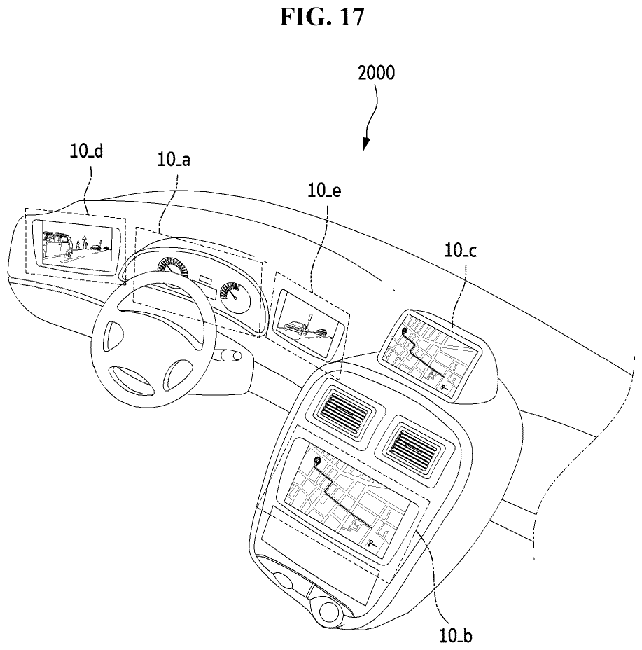

FIG. 17 is an illustrative view illustrating an instrument board and a center fascia of a vehicle including display devices 10_a, 10_b, 10_c, 10_d, and 10_e according to one or more embodiments. For example, a vehicle to which display devices 10_a, 10_b, 10_c, 10_d, and 10_e according to one or more embodiments are applied is illustrated in FIG. 17.

Referring to FIG. 17, the display devices 10_a, 10_b, and 10_c according to one or more embodiments may be applied to an instrument board of the vehicle, applied to a center fascia of the vehicle, and/or applied to a center information display (CID) on a dashboard of the vehicle. In one or more embodiments, the display devices 10_d and 10_e according to one or more embodiments may be applied to a room mirror display that substitutes for a side mirror of the vehicle.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

A display device/apparatus, an electronic device/apparatus, a vehicle, a device/apparatus for manufacturing substantially the same and/or any other relevant devices, apparatus, or components according to embodiments of the present disclosure described herein may be implemented by utilizing any suitable hardware, firmware (e.g., an application-specific integrated circuit), software, or a combination of software, firmware, and hardware. For example, the one or more suitable components of the device may be formed or provided on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components to perform the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

The display device according to one or more embodiments may be applied to one or more suitable electronic devices. The electronic device according to one or more embodiments may include the display device as described in one or more embodiments and may further include modules or devices having additional functions in addition to the display device.

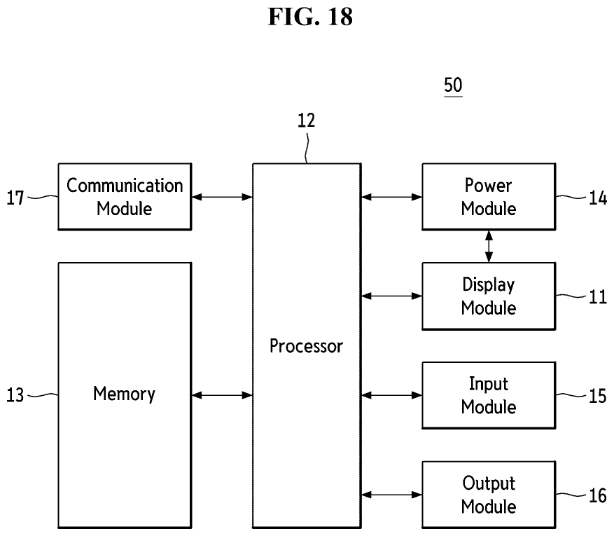

FIG. 18 is a block diagram of an electronic device according to one or more embodiments. Referring to FIG. 18, the electronic device 50 according to one or more embodiments may include a display module, a processor 12, a memory 13, and a power module 14. The electronic device 5000 may further include an input module 14, a non-image output module 15, and/or a communication module 16.

The electronic device 50 may output one or more suitable information in the form of images through the display module 11. If (e.g., when) the processor 12 executes an application stored in the memory 13, image information provided by the application may be provided to the user through the display module 1100. The power module 14 may include a power supply module, such as a power adapter and/or a battery device, and a power conversion module that converts the power supplied by the power supply module to generate power required or desired for the operation of the electronic device 5000. The input module 14 may provide input information to the processor 12 and/or the display module 11. The non-image output module 15 may receive information other than images transmitted from the processor 12, such as sound, haptics, and/or light, and provide the information to the user. The communication module 16 may be a module that is responsible for transmitting and receiving information between the electronic device 5000 and an external device, and may include a receiving unit and a transmitting unit.

At least one selected from among the components of the electronic device 50 as described in one or more embodiments may be included in the display device as described in one or more embodiments. In one or more embodiments, one or more of the individual modules functionally included in one module may be included in the display device, and others may be provided separately from the display device. For example, the display device may include a display module 11, and the processor 12, memory 13, and power module 14 may be provided in the form of other devices within the electronic device 11 other than the display device.

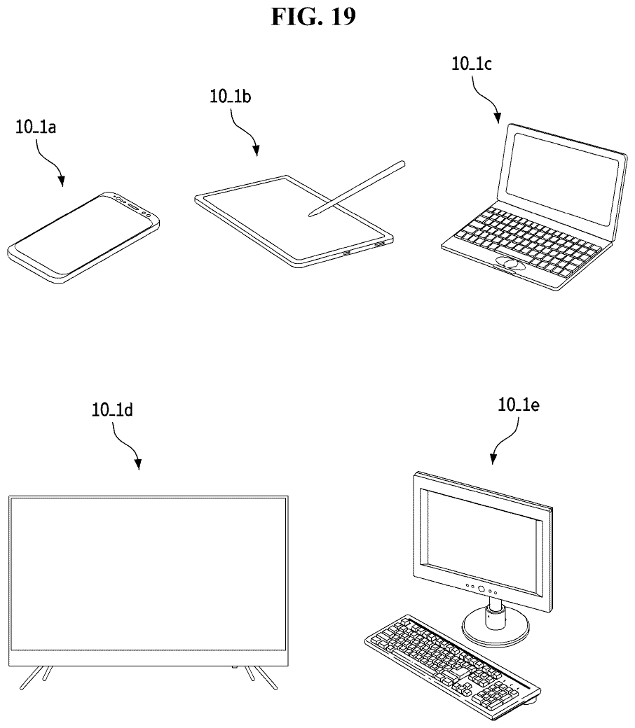

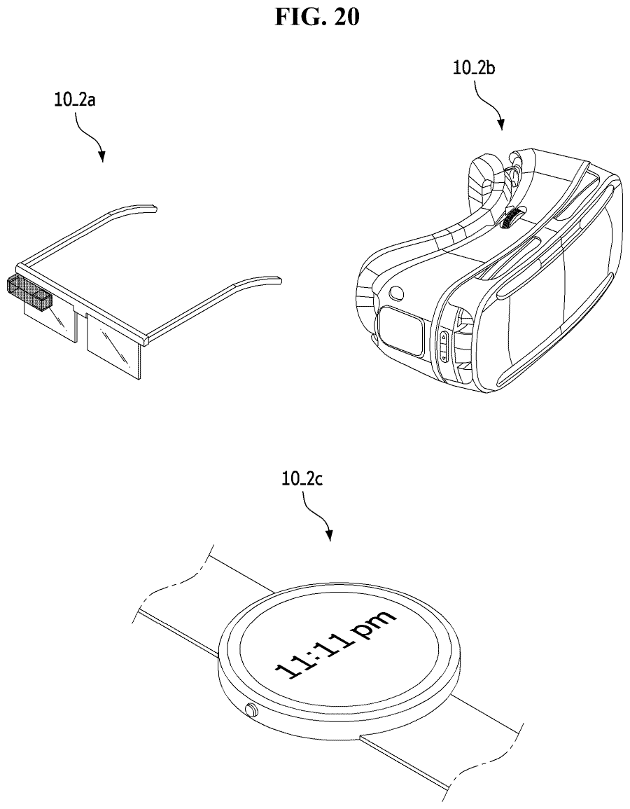

FIGS. 19 and 20 are schematic diagrams of electronic devices according to one or more embodiments. FIGS. 19 and 20 illustrate examples of one or more electronic devices to which the display device according to one or more embodiments is applied.

FIG. 19 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module, such as a touch sensor, and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they may also include display modules and input modules similar to smartphones 10_1 and may additionally include communication modules in one or more suitable cases.

FIG. 20 illustrates an example of an electronic device including a display module being applied to a wearable electronic device. The wearable electronic device may be a smart glasses 10_2a, a head-mounted display 10_2b, a smart watch 10_2c, and/or the like.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c may include a biometric sensor as an input device and may provide biometric information recognized by the biometric sensor to the user through the display module.

It will be understood by one of ordinary skill in the art to which the present disclosure belongs that the present disclosure may be implemented in one or more suitable forms without changing the spirit and scope of the present disclosure. Therefore, it will be understood that the one or more embodiments as described in the present disclosure are illustrative rather than being restrictive in all aspects. It will be understood that the scope of the present disclosure are defined by the scope of the appended claims and equivalents thereof rather than the detailed description as described above and all modifications and alterations derived from the appended claims and their equivalents fall within the scope of the present disclosure.

What is claimed is:

1. A display device, comprising:
a substrate;
an anode electrode on the substrate;
a light emitting stack on the anode electrode;
a pixel defining layer on the light emitting stack and having a trench; and
a cathode electrode on the light emitting stack and the pixel defining layer,
wherein the anode electrode comprises:
a plurality of conductive layers;
a protruding pattern protruding toward the light emitting stack from one selected from among the plurality of conductive layers; and
an insulating layer around the protruding pattern and comprising silver and nitrogen.

2. The display device as claimed in claim 1, wherein the insulating layer comprises silver nitride.

3. The display device as claimed in claim 1, wherein the insulating layer comprises silver nitrate.

4. The display device as claimed in claim 1, wherein the protruding pattern has a circular cross-sectional shape.

5. The display device as claimed in claim 1, wherein the insulating layer is between the protruding pattern and the light emitting stack.

6. The display device as claimed in claim 1, wherein the protruding pattern comprises silver.

7. The display device as claimed in claim 1, wherein the insulating layer has specific resistance of about 615 nΩcm at 20° C.

8. The display device as claimed in claim 1, wherein the insulating layer has a thickness greater than or equal to about 50 Å.

9. The display device as claimed in claim 1, wherein the plurality of conductive layers comprise:
a first conductive layer;
a second conductive layer on the first conductive layer and comprising silver; and
a third conductive layer on the second conductive layer,
wherein each of the first conductive layer and the third conductive layer comprises a transparent conductive material.

10. The display device as claimed in claim 9, wherein the protruding pattern extends from the second conductive layer and protrudes to the outside of the anode electrode through a pin hole of the third conductive layer.

11. A vehicle comprising a display device, wherein the display device comprises:
a substrate;
an anode electrode on the substrate;
a light emitting stack on the anode electrode;
a pixel defining layer on the light emitting stack and having a trench; and
a cathode electrode on the light emitting stack and the pixel defining layer,
wherein the anode electrode comprises:
a plurality of conductive layers;
a protruding pattern protruding toward the light emitting stack from one selected from among the plurality of conductive layers; and
an insulating layer around the protruding pattern and comprising silver and nitrogen.

12. The vehicle as claimed in claim 11, wherein the insulating layer comprises silver nitride.

13. The vehicle as claimed in claim 11, wherein the insulating layer comprises silver nitrate.

14. The vehicle as claimed in claim 11, wherein the protruding pattern comprises silver.

15. The vehicle as claimed in claim 11, wherein the insulating layer has specific resistance of about 615 nΩcm at 20° C.

16. The vehicle as claimed in claim 11, wherein the insulating layer has a thickness greater than or equal to about 50 Å.

17. The vehicle as claimed in claim 11, wherein the plurality of conductive layers comprise:
a first conductive layer;
a second conductive layer on the first conductive layer and comprising silver; and
a third conductive layer on the second conductive layer,
wherein each of the first conductive layer and the third conductive layer comprises a transparent conductive material.

18. The vehicle as claimed in claim 17, wherein the protruding pattern extends from the second conductive layer and protrudes to the outside of the anode electrode through a pin hole of the third conductive layer.

19. An electronic device, comprising a display device comprising:
a substrate;
an anode electrode on the substrate;
a light emitting stack on the anode electrode;
a pixel defining layer on the light emitting stack and having a trench; and
a cathode electrode on the light emitting stack and the pixel defining layer,
wherein the anode electrode comprises:
a plurality of conductive layers;
a protruding pattern protruding toward the light emitting stack from one selected from among the plurality of conductive layers; and
an insulating layer around the protruding pattern and comprising silver and nitrogen.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
